(19) United States
(12) Patent Application Publication
(10) Pub. No.: US 2013/0043538 A1
(43) Pub. Date: Feb. 21, 2013

(54) Switch

(71) Applicant: Chao-Cheng Lu, Taipei (TW)

(72) Inventor: Chao-Cheng Lu, Taipei (TW)

(21) Appl. No.: 13/136,911

(22) Filed: Aug. 16, 2011

(51) Int. Cl. H01L 27/092

(52) U.S. Cl. 257/368; 257/E27.062

(57) ABSTRACT

The switch in this invention is connected in series with two field effect transistor, comprises: the source S1 of first N-channel FET F1 and the source S2 of second N-channel FET F2 are directly connected together form a third terminal VA, the gate G1 of first N-channel FET F1 and the gate G2 of second N-channel FET F2 are connected together form a control terminal GA, the drain D1 of first N-channel FET F1 form a first terminal D1, the drain D2 of second N-channel FET F2 form a second terminal D2, the body diode DA of first N-channel FET F1 and the body diode DB of second N-channel FET F2, are back-to-back series connected together, the right side equivalent circuit F are first N-channel FET F1 and second N-channel FET F2 equivalent circuit, form a switch F of the present invention.

### BACKGROUND OF THE INVENTION

The present invention relates generally to electric circuit switch, the includes series-connected circuit of first and second N-channel field effect transistor or series-connected circuit of first and second P-channel field effect transistor.

### SUMMARY OF THE INVENTION

In order to provide switch devices that may elevate the efficiency and simplify of switch circuit, the present invention is proposed the following object:

The first object of the invention is to provide switch for switch circuit that eliminate drawback of high power consumption.

The second object of the invention is to provide a switch circuit having a control terminal, first terminal, second terminal and third terminal.

The third object of the invention is use a having body diode field effect transistor (FET) or a having no body diode FET.

The fourth object of the invention is use a semiconductor, that at lest comprises Metal oxide semiconductor field effect transistor (MOSFET), Junction field effect transistor (JFET), Silicon carbide junction field effect transistor (SIC JFET).

According to the defects of a mechanical switch technology discussed above, a novel solution, the switch is proposed in the present invention, which provides high efficiency in switch circuit.

### BRIEF DESCRIPTION OF THE INVENTION

Embodiment of the invention will be described in more detail hereinafter with reference to the accompanying drawing. In the drawings:

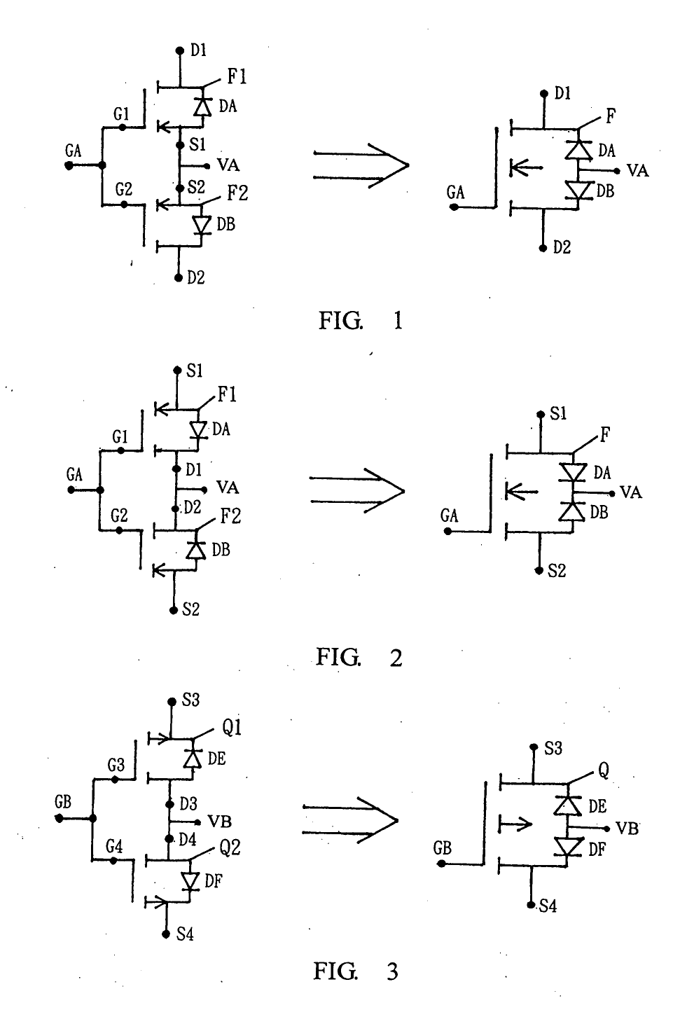

FIG. 1 shows a circuit diagram of a first embodiment of the present invention.

FIG. 2 shows a circuit diagram of a second embodiment of the present invention.

FIG. 3 shows a circuit diagram of a third embodiment of the present invention.

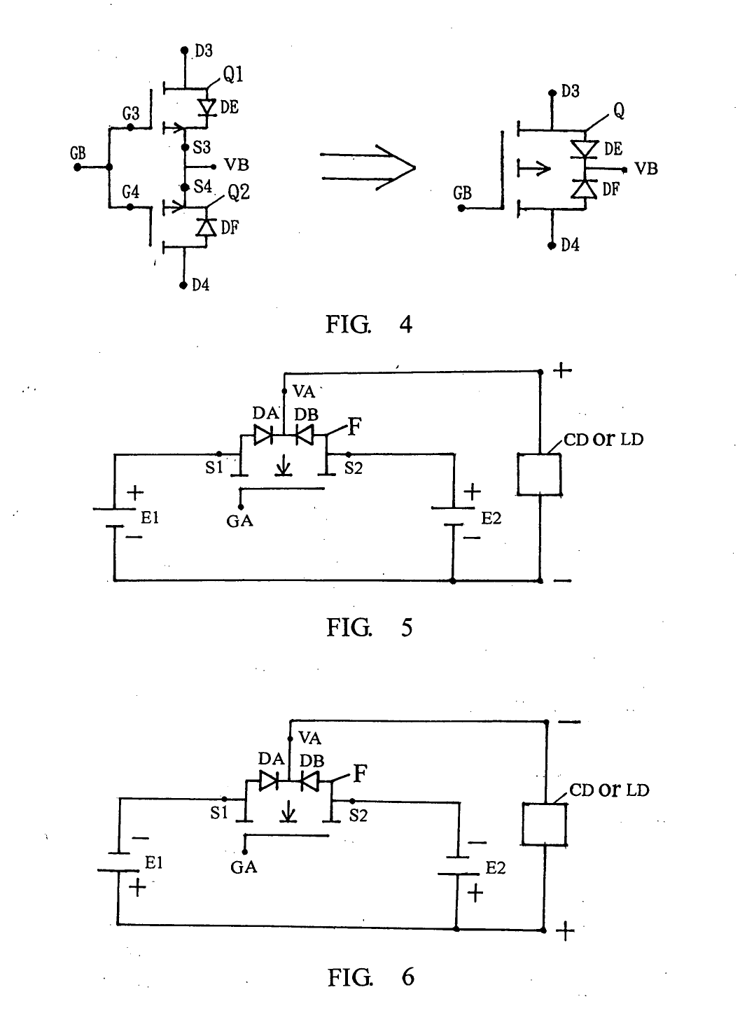

FIG. 4 shows a circuit diagram of a fourth embodiment of the present invention.

FIG. 5 shows a circuit diagram of a first switch circuit of the present invention.

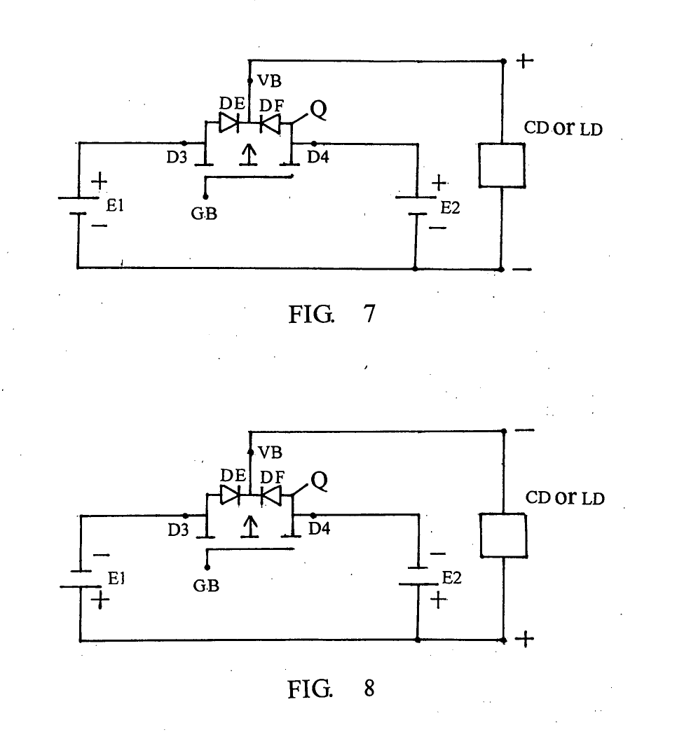

FIG. 6 shows a circuit diagram of a second switch circuit of the present invention.

FIG. 7 shows a circuit diagram of a third switch circuit of the present invention.

FIG. 8 shows a circuit diagram of a fourth switch circuit of the present invention.

### DESCRIPTION OF THE PREFERRED EMBODIMENT

FIG. 1 shows a circuit diagram of a first embodiment of the present invention. In FIG. 1, the series-connected circuit of first N-channel field effect transistor (FET) F1 and second N-channel FET F2, the source S1 of first N-channel FET F1 and the source S2 of second N-channel FET F2 are directly connected together form a third terminal VA, the gate G1 of first N-channel FET F1 and the gate G2 of second N-channel FET F2 are connected together form a control terminal GA, the drain D1 of first N-channel FET F1, form a first terminal D1, the drain D2 of second N-channel FET F2, form a second terminal D2, the body diode DA of first N-channel FET F1, and the body diode DB of second N-channel FET F2, are back-to-back series connected together, the right side equivalent circuit F of FIG. 1 are first N-channel FET F1 and second N-channel FET F2 equivalent circuit, form a switch F of the present invention.

In FIG. 1, when control terminal GA is positive voltage, the first terminal D1 of first N-channel FET F1 and the second terminal D2 of second N-channel FET F2 is turn on, the third terminal VA can be use for power input or power output; when control terminal GA is negative voltage, the first terminal D1 of first N-channel FET F1 and the second terminal D2 of second N-channel FET F2 is turn off, the third terminal VA can be use for power input by the body diode DA of first N-channel FET F1 and the body diode DB of second N-channel FET F2; if first N-channel FET F1 and second N-channel FET F2 use having no body diode N-channel FET, when control terminal GA is negative voltage, the first N-channel FET F1 and second N-channel FET F2 is turn off, the third terminal VA can not power input or power output in the switch F.

FIG. 2 shows a circuit diagram of a second embodiment of the present invention. In FIG. 2, the series-connected circuit of first N-channel FET F1 and second N-channel FET F2, the drain D1 of first N-channel FET F1 and the drain D2 of the second N-channel FET F2 are directly connected together form a third terminal VA, the gate G1 of first N-channel FET F1 and the gate G2 of second N-channel FET F2 are connected together form a control terminal GA, the source S1 of first N-channel FET F1, form a first terminal S1, the source S2 of second N-channel FET F2, form a second terminal S2, the body diode DA of first N-channel FET F1, and the body diode DB of the second N-channel FET F2, are face-to-face series connected together, the right side equivalent circuit F of FIG. 2 are first N-channel FET F1 and second N-channel FET F2 equivalent circuit, form a switch F of the present invention.

In FIG. 2, when control terminal GA is positive voltage, the source S1 of first N-channel FET F1 and the source S2 of second N-channel FET F2 is turn on; when control terminal GA is negative voltage, the source S1 of first N-channel FET F1 and the source S2 of second N-channel FET F2 is turn off, the third terminal VA can be use for power output by the body diode DA of first N-channel FET F1 and the body diode DB of second N-channel FET F2; if first N-channel FET F1 and second N-channel FET F2 use having no body diode N-channel FET, when control terminal GA is negative voltage, the first N-channel FET F1 and second N-channel FET F2 is turn off, the third terminal VA can not power input or power output in the switch F.

FIG. 3 shows a circuit diagram of a third embodiment of the present invention. In FIG. 3, the series-connected circuit of first P-channel FET Q1 and second P-channel FET Q2, the drain D3 of first P-channel FET Q1 and the drain D4 of the second P-channel FET Q2 are directly connected together form a third terminal VB, the gate G3 of first P-channel FET Q1 and the gate G4 of second P-channel FET Q2 are connected together form a control terminal GB, the source S3 of first P-channel FET Q1, form a first terminal S3, the source S4 of second P-channel FET Q2, form a second terminal S4, the body diode DE of first P-channel FET Q1, the body diode DF of second P-channel FET Q2, are back-to-back series connected together, the right side equivalent circuit Q of FIG. 3 are first P-channel FET Q1 and second P-channel FET Q2 equivalent circuit, form a switch Q of the present invention.

In FIG. 3, when control terminal GB is negative voltage, the source S3 of the first P-channel FET Q1 and the source S4 of the second P-channel FET Q2 is turn on; when control terminal GB is positive voltage, the source S3 of first P-channel FET Q1 and the source S4 of second P-channel FET Q2 is turn off, the third terminal VB can be use for power input by the body diode DE of first N-channel FET F1 and the body diode DF of second N-channel FET F2; if first P-channel FET Q1 and second P-channel FET Q2 use having no body diode P-channel FET, when control terminal GB is positive voltage, the first P-channel FET Q1 and second P-channel FET Q2 is turn off, the third terminal VB can not power input or power output in the switch Q.

FIG. 4 shows a circuit diagram of a second embodiment of the present invention. In FIG. 4, the series-connected circuit of first P-channel FET Q1 and second P-channel FET Q2, the source S3 of first P-channel FET Q1 and the source S4 of second P-channel FET Q2 are directly connected together form a third terminal VB, the gate G3 of first P-channel FET Q1 and the gate G4 of second P-channel FET Q2 are connected together form a control terminal GB, the drain D3 of first P-channel FET Q1, form a first terminal D3, the drain D4 of second P-channel FET Q2, form a second terminal D4, the body diode DE of the first P-channel FET Q1, the body diode DF of second P-channel FET Q2, are face-to-face series connected together, the right side equivalent circuit Q of FIG. 4 are the first P-channel FET Q1 and second P-channel FET Q2 equivalent circuit, form a switch Q of the present invention.

In FIG. 4, when control terminal GB is negative voltage, the drain D3 of first P-channel FET Q1 and the drain D4 of second P-channel FET Q2 is turn on; when control terminal GA is positive voltage, the drain D3 of first P-channel FET Q1 and the drain D4 of second P-channel FET Q2 is turn off, the third terminal VB can be use for power output by the body diode DE of first N-channel FET F1 and the body diode DF of second N-channel FET F2; if first P-channel FET Q1 and second P-channel FET Q2 use having no body diode P-channel FET, when control terminal GB is positive voltage, the first P-channel FET Q1 and second P-channel FET Q2 is turn off, the third terminal VB can not power input or power output in the switch Q.

FIG. 5, shows a circuit diagram of a first switch circuit of the present invention. In FIG. 5, first terminal S1 of switch F connected to positive terminal of first cell E1, second terminal S2 of switch F connected to positive terminal of second cell E2, third terminal VA of switch F connected to positive terminal of charge device CD or load LD, the negative terminal of first cell E1 and negative terminal of second cell E2 connected together to negative terminal of charge device CD or load LD, the control terminal GA connected to external control voltage terminal.

In FIG. 5, the operation theorem of cell discharge of present invention, if a control voltage terminal connected to control terminal GA of switch F is negative voltage, the switch F is turn off, while a positive terminal of load LD connected to the third terminal VA of switch F and negative terminal of load LD connected to negative terminal of first cell E1 and connected to negative terminal of second cell E2, the current of first cell E1 passes through the body diode DA, and the current of second cell E2 passes through the body diode DB, third terminal VA, load LD and back to negative terminal of first cell E1 and back to negative terminal of second cell E2.

In FIG. 5, the operation theorem of cell charge of present invention, if a control voltage terminal connected to control terminal GA of switch F is positive voltage, the switch F is turn on, while the positive voltage terminal of charge device CD, the current of positive voltage passes through the third terminal VA, switch F, first terminal S1, positive terminal of first cell E1, negative terminal of first cell E1, and back to negative voltage terminal of charge device CD, another current o positive voltage passes through the third terminal VA, switch F, second terminal S2, positive terminal of second cell E2, negative terminal of second cell E2, and back to negative voltage terminal of charge device CD; the third terminal VA of present invention, can be provide a voltage to external electric circuit, such as sense voltage input of voltage protection IC of the load LD, or other protection circuit.

FIG. 6, shows a circuit diagram of a second switch circuit of the present invention. In FIG. 6, first terminal S1 of switch F connected to negative terminal of first cell E1, second terminal S2 of switch F connected to negative terminal of second cell E2, third terminal VA of switch F connected to negative terminal of charge device CD or load LD, the positive terminal of first cell E1 and positive terminal of second cell E2 connected together to positive terminal of charge device CD or load LD, the control terminal GA connected to external control voltage terminal.

In FIG. 6, the operation theorem of cell discharge of present invention, if a control voltage terminal connected to control terminal GA of switch F is negative voltage, the switch F is turn off, while a negative terminal of load LD connected to the third terminal VA of switch F and positive terminal of load LD connected to positive terminal of first cell E1 and connected to positive terminal of second cell E2, the current of first cell E1 can not passes through the body diode DA, and the current of second cell E2 can not passes through the body diode DB.

In FIG. 6, the operation theorem of cell charge of present invention, if a control voltage terminal connected to control terminal GA of switch F is positive voltage, the switch F is turn on, while the positive voltage terminal of charge device CD, the current of positive voltage passes through the positive terminal of first cell E1, negative terminal of first cell E1, first terminal S1, switch F, third terminal VA, and back to negative voltage terminal of charge device CD, another current of positive voltage passes through the positive terminal of second cell E2, negative terminal of second cell E2, second terminal S2, switch F, third terminal VA, and back to negative voltage terminal of charge device CD.

FIG. 7, shows a circuit diagram of a third switch circuit of the present invention. In FIG. 7, first terminal D3 of switch Q connected to positive terminal of first cell E1, second terminal D4 of switch Q connected to positive terminal of second cell E2, third terminal VB of switch Q connected to positive terminal of charge device CD or load LD, the negative terminal of first cell E1 and negative terminal of second cell E2 connected together to negative terminal of charge device CD or load LD, the control terminal GA connected to external control voltage terminal.

In FIG. 7, the operation theorem of cell discharge of present invention, if a control voltage terminal connected to control terminal GA of switch Q is positive voltage, the switch Q is turn off, while a positive terminal of load LD connected to the third terminal VB of switch Q and negative terminal of load LD connected to negative terminal of first cell E1 and connected to negative terminal of second cell E2, the current of first cell E1 passes through the body diode DE, and the current of second cell E2 passes through the body diode DF, third terminal VA, load LD and back to negative terminal of first cell E1 and back to negative terminal of second cell E2.

In FIG. 7, the operation theorem of cell charge of present invention, if a control voltage terminal connected to control terminal GB of switch Q is negative voltage, the switch Q is turn on, while the positive voltage terminal of charge device CD, the current of positive voltage passes through the third terminal VB, switch Q, first terminal D3, positive terminal of first cell E1, negative terminal of first cell E1, and back to negative voltage terminal of charge device CD, another current of positive voltage passes through the third terminal VB, switch Q, second terminal D4, positive terminal of second cell E2, negative terminal of second cell E2, and back to negative voltage terminal of charge device CD; the third terminal VB of present invention, can be provide a voltage to external electric circuit, such as sense voltage input of voltage protection IC of the load LD, or other protection circuit.

FIG. 8, shows a circuit diagram of a fourth switch circuit of the present invention. In FIG. 8, first terminal D3 of switch Q connected to negative terminal of first cell E1, second terminal D4 of switch Q connected to negative terminal of second cell E2, third terminal VB of switch Q connected to negative terminal of charge device CD or load LD, the positive terminal of first cell E1 and positive terminal of second cell E2 connected together to positive terminal of charge device CD or load LD, the control terminal GA connected to external control voltage terminal.

In FIG. 8, the operation theorem of cell discharge of present invention, if a control voltage terminal connected to control terminal GB of switch Q is positive voltage, the switch F is turn off, while a negative terminal of load LD connected to the third terminal VB of switch Q and positive terminal of load LD connected to positive terminal of first cell E1 and connected to positive terminal of second cell E2, the current of first cell E1 can not passes through the body diode DE, and the current of second cell E2 can not passes through the body diode DF.

In FIG. 8, the operation theorem of cell charge of present invention, if a control voltage terminal connected to control terminal GB of switch F is negative voltage, the switch Q is turn on, while the positive voltage terminal of charge device CD, the current of positive voltage passes through the positive terminal of first cell E1, negative terminal of first cell E1, first terminal D3, switch Q, third terminal VB, and back to negative voltage terminal of charge device CD, another current of positive voltage passes through the positive terminal of second cell E2, negative terminal of second cell E2, second terminal D4, switch Q, third terminal VB, and back to negative voltage terminal of charge device CD.

What is claimed is:

1. A switch is for switch circuit on the source of first field effect transistor (FET) and the source of second FET are directly connected together form a third terminal, characterized in that it comprises:
a control terminal is a gate of said first FET and a gate of said second FET connected together in a terminal;
a first terminal is a drain of said first FET; and
a second terminal is a drain of said second FET.

2. A switch as claimed in claim 1, wherein said first FET and said second FET each comprises an N-channel FET.

3. A switch as claimed in claim 1, wherein said first FET and said second FET each comprises a P-channel FET.

4. A switch as claimed in claim 1, wherein said control terminal coupled to control voltage terminal.

5. A switch as claimed in claim 1, wherein said first terminal coupled to positive terminal or negative terminal of said first cell.

6. A switch as claimed in claim 1, wherein said second terminal coupled to positive terminal or negative terminal of said second cell.

7. A switch as claimed in claim 1, wherein said third terminal coupled to positive terminal or negative terminal of said charge device or said load.

8. A switch as claimed in claim 1, wherein said third terminal coupled to sense voltage input of voltage protection IC.

9. A switch is for switch circuit on the drain of first FET and the drain of second FET are directly connected together form a third terminal, characterized in that it comprises:
a control terminal is a gate of said first FET and a gate of said second FET connected together in a terminal;
a first terminal is a source of said first FET; and
a second terminal is a source of said second FET.

10. A switch as claimed in claim 9, wherein said first FET and said second FET each comprises an N-channel.

11. A switch as claimed in claim 9, wherein said first FET and said second FET each comprises a P-channel FET.

12. A switch as claimed in claim 9, wherein said control terminal coupled to control voltage terminal.

13. A switch as claimed in claim 9, wherein said first terminal coupled to positive terminal or negative terminal of said first cell.

14. A switch as claimed in claim 9, wherein said second terminal coupled to positive terminal or negative terminal of said second cell.

15. A switch as claimed in claim 9, wherein said third terminal coupled to positive terminal or negative terminal of said charge device or said load.

16. A switch as claimed in claim 9, wherein said third terminal coupled to sense voltage input of voltage protection IC.
